(19) United States
(12) Patent Application Publication
(10) Pub. No.: US 2017/0077354 A1
(43) Pub. Date: Mar. 16, 2017

(54) LIGHT EMITTING DEVICE

(71) Applicant: LG INNOTEK CO., LTD., Seoul (KR)

(72) Inventors: Koh Eun LEE, Seoul (KR); Ga Yeon KIM, Seoul (KR); Hwan Hee JEONG, Seoul (KR)

(73) Assignee: LG INNOTEK CO., LTD., Seoul (KR)

(21) Appl. No.: 15/125,500

(22) PCT Filed: Nov. 14, 2014
(86) PCT No.: PCT/KR2014/010980

§ 371 Date: Sep. 12, 2016

(30) Foreign Application Priority Data
Mar. 13, 2014 (KR) 10-2014-0029840

(51) Int. Cl. H01L 33/38; H01L 33/46; H01L 33/62; H01L 33/14

(52) U.S. Cl. CPC H01L 33/382; H01L 33/145; H01L 33/46; H01L 33/62

(57) ABSTRACT

One embodiment provides a light emitting device comprising: a substrate; a first electrode arranged on the substrate; a light emitting structure arranged on the first electrode and including a first semiconductor layer, a second semiconductor layer, and an active layer between the first and second semiconductor layers; and a second electrode arranged on the second semiconductor layer, wherein the second electrode includes: a pad electrode; and a branch electrode extending from the pad electrode and having a hexagonal structure for enabling an upper surface of the second semiconductor layer to be exposed in a hexagonal shape.

### TECHNICAL FIELD

Embodiments relate to a light emitting device.

### BACKGROUND ART

Light emitting diode (LED) as a representative example of a light emitting device which convert electrical signals into infrared light, visible light or other light using characteristics of compound semiconductors. Such LEDs are utilized in home appliances, remote controllers, electronic bulletin boards, displays and various other automated machines, and the application range thereof is gradually increasing.

Generally, miniaturized LEDs are fabricated into surface mount devices so as to be directly mounted on a printed circuit board (PCB) and hence, an LED lamp, which serves as a display device, is being developed into a surface mount device. The surface mount device can substitute for a conventional simple on/off lamp and is used for an on/off-signal display, a character display, and an image display, which are color displays.

The increased application range of LEDs causes demand for higher brightness household lights as well as emergency lights and therefore, it is important to enhance brightness of LEDs.

### DISCLOSURE

### Technical Problem

Embodiments provide a light emitting device having an improved electrode structure for enlarging the light emission area of a light emitting structure.

### Technical Solution

In one embodiment, a light emitting device includes a substrate, a first electrode disposed on the substrate, a light emitting structure disposed on the first electrode, the light emitting structure including a first semiconductor layer, a second semiconductor layer and an active layer disposed between the first and second semiconductor layers, and a second electrode disposed on the second semiconductor layer, wherein the second electrode includes a pad electrode, and a branch electrode extending from the pad electrode while having hexagonal.

In another embodiment, a light emitting device includes a substrate, a first electrode disposed on the substrate, a light emitting structure disposed on the first electrode, the light emitting structure including a first semiconductor layer, a second semiconductor layer and an active layer disposed between the first and second semiconductor layers, a second electrode disposed on the second semiconductor layer, and a current blocking layer disposed between the first electrode and the first semiconductor layer, wherein the second electrode includes a pad electrode, and a branch electrode extending from the pad electrode while having hexagonal frames, wherein at least a portion of the current blocking layer vertically overlaps the branch electrode.

### Advantageous Effects

In the light emitting device according to each embodiment, the second electrode, which has the hexagonal frames, is disposed on the upper surface of the second semiconductor layer such that the upper surface of the second semiconductor layer has hexagonal portions. Accordingly, it may be possible to reduce the width of the second electrode. It may also be possible to uniformly supply electric power to the upper surface of the second semiconductor layer. As a result, there may be an advantage in that the light emission area of the active layer is increased.

### DESCRIPTION OF DRAWINGS

FIG. 1 is a perspective view illustrating a light emitting device according to an embodiment.

FIG. 2 is a sectional perspective view illustrating a cross-section of the light emitting device illustrated in FIG. 1.

FIG. 3 is a perspective view illustrating a second electrode illustrated in FIG. 1.

FIGS. 4 to 6 are sectional views illustrating various embodiments of the above-described light emitting device.

FIG. 7 is an exploded perspective view illustrating a display apparatus according to a first embodiment.

FIG. 8 is a sectional view illustrating a display apparatus according to a second embodiment.

FIG. 9 is an exploded perspective view illustrating a lighting apparatus according to an embodiment.

### BEST MODE

Reference will now be made in detail to embodiments, examples of which are illustrated in the accompanying drawings. However, the present disclosure may be embodied in many different forms and should not be construed as limited to the embodiments set forth herein. Rather, these embodiments are provided so that this disclosure will be thorough and complete, and will fully convey the scope of the disclosure to those skilled in the art. The present disclosure is defined only by the categories of the claims. In certain embodiments, detailed descriptions of device constructions or processes well known in the art may be omitted to avoid obscuring appreciation of the disclosure by a person of ordinary skill in the art. Wherever possible, the same reference numbers will be used throughout the drawings to refer to the same or like parts.

Spatially-relative terms such as “below”, “beneath”, “lower”, “above”, or “upper” may be used herein to describe one element's relationship to another element as illustrated in the Figures. It will be understood that spatially-relative terms are intended to encompass different orientations of the device in addition to the orientation depicted in the Figures. For example, if the device in one of the figures is turned over, elements described as “below” or “beneath” other elements would then be oriented “above” the other elements. The exemplary terms “below” or “beneath” can, therefore, encompass both an orientation of above and below. Since the device may be oriented in another direction, the spatially-relative terms may be interpreted in accordance with the orientation of the device.

The terminology used in the present disclosure is for the purpose of describing particular embodiments only and is not intended to limit the disclosure. As used in the disclosure and the appended claims, the singular forms “a”, “an” and “the” are intended to include the plural forms as well, unless context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

In the drawings, the thickness or size of each layer is exaggerated, omitted, or schematically illustrated for convenience in description and clarity. Also, the size or area of each constituent element does not entirely reflect the actual size thereof

Angles or directions used to describe the structures of light emitting devices according to embodiments are based on the drawings. Unless there is, in the specification, no definition of a reference point to describe angular positional relations in the structures of the light emitting devices, the associated drawings may be referred to.

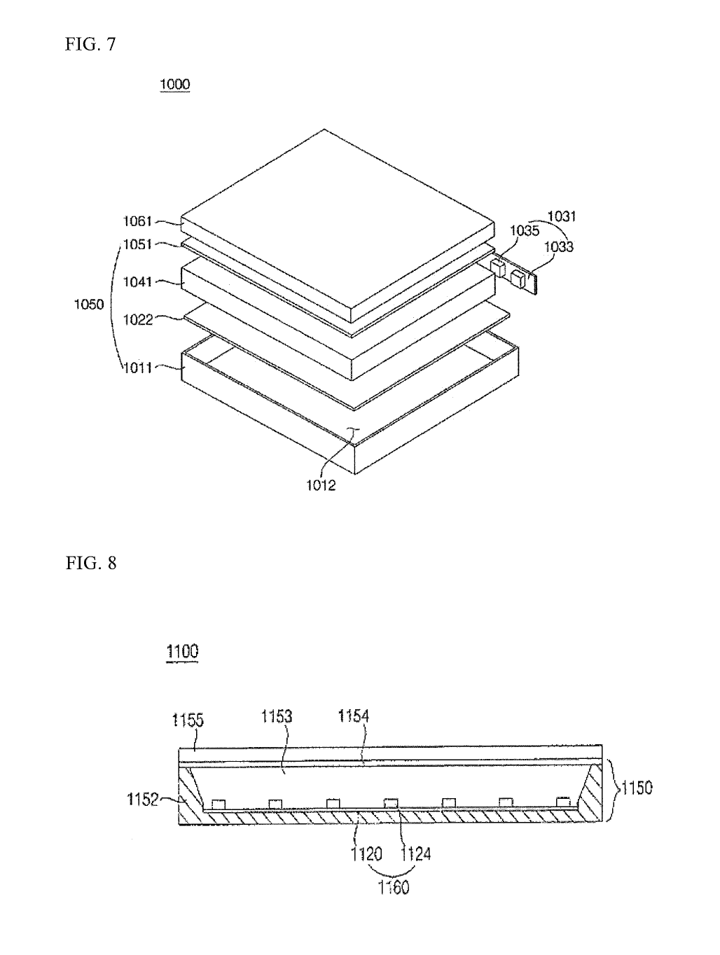

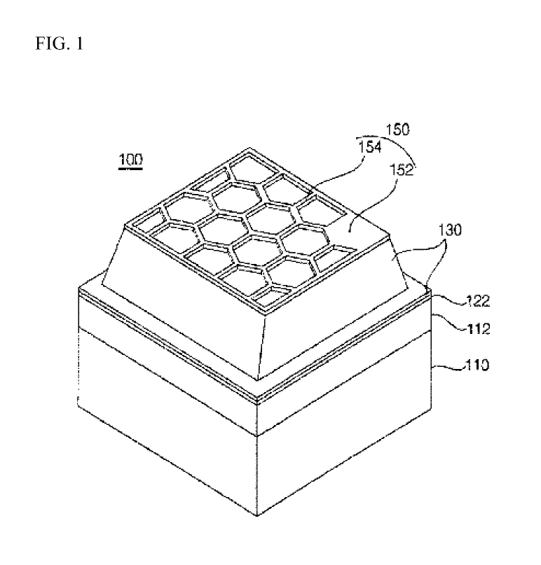

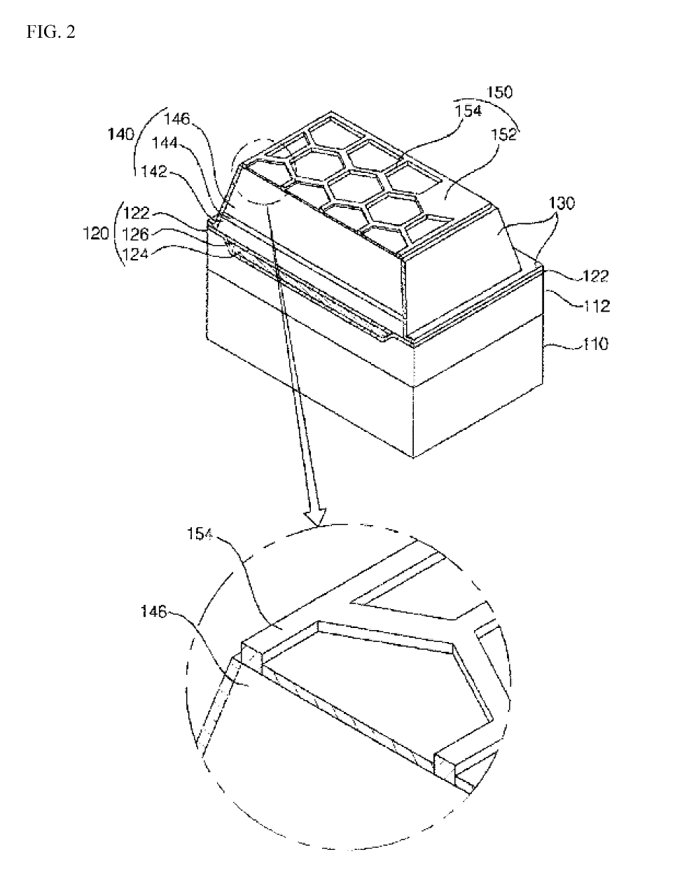

FIG. 1 is a perspective view illustrating a light emitting device according to an embodiment. FIG. 2 is a sectional perspective view illustrating a cross-section of the light emitting device illustrated in FIG. 1. FIG. 3 is a perspective view illustrating a second electrode illustrated in FIG. 1.

Referring to FIGS. 1 to 3, the light emitting device, which is designated by reference numeral “100”, includes a substrate 110, a first electrode disposed on the substrate 110, a light emitting structure 140 disposed on the first electrode 120, and a second electrode 150 disposed on the light emitting structure 140.

The substrate 110 may be made of a material having excellent thermal conductivity. Alternatively, the substrate 110 may be made of a conductive material. For example, the substrate 110 may be made of a metal material or a conductive ceramic. The substrate 110 may have a single-layer structure. Alternatively, the substrate 110 may have a double-layer structure or a multilayer structure having three or more layers.

That is, the substrate 110 may be made of a metal material, for example, one selected from Au, Ni, W, Mo, Cu, Al, Ta, Ag, Pt, Cr, and alloys thereof. The substrate 110 may be formed by stacking two or more layers of different materials. Alternatively, the substrate 110 may be formed using a carrier wafer such as Si, Ge, GaAs, ZnO, SiC, SiGe, GaN, or Ga₂O₃.

The substrate 110 functions to easily dissipate heat generated from the light emitting device 100, and thus achieves an enhancement in thermal stability.

A first metal layer 112 may be disposed on the substrate 110.

The first metal layer 112 may be formed to achieve bonding of the first electrode 120 to the substrate 120. For example, the first metal layer 112 may include at least one of gold (Au), tin (Sn), indium (In), silver (Ag), nickel (Ni), niobium (Nb), aluminum (Al), palladium (Pd), and copper (Cu).

In addition, the first metal layer 112 may be made of a material capable of preventing metal diffusion. For example, the first metal layer 112 may include, at least one of platinum (Pt), palladium (Pd), tungsten (W), nickel (Ni), ruthenium (Ru), molybdenum (Mo), iridium (Ir), rhodium (Rh), tantalum (Ta), hafnium (Hf), zirconium (Zr), niobium (Nb), vanadium (V); iron (Fe), and titanium (Ti), or an alloy thereof, but the present disclosure is not limited thereto.

The first metal layer 112 may minimize mechanical damage such as breakage or peeling-off, which may be generated during fabrication of the light emitting device 100.

In addition, the first metal layer 112 may prevent diffusion of the metal material of the substrate 110 into the light emitting structure 140.

The first metal layer 112 may be formed using a sputtering method. In an embodiment, the first metal layer 112 may be formed using an electrochemical deposition method, a bonding method using a eutectic metal or the like. The first metal layer 112 may have a multilayer structure.

As illustrated in FIG. 2, the first electrode 120 may be disposed on the first metal layer 112. The first electrode 120 may include at least one of a second metal layer 122, a reflective layer 124 and an ohmic layer 126. For example, the first electrode 120 may have, a stacked structure of the second metal layer 122, the reflective layer 124 and the ohmic layer 126, a stacked structure of the reflective layer 12 and the ohmic layer 126, or a stacked structure of the second metal layer 122 and the reflective layer 124, but the present disclosure is not limited thereto. For example, the first electrode 120 may have a structure in which the reflective layer and ohmic layer 126 are sequentially stacked over the second metal layer 122.

The second metal layer 122 may include a barrier metal or a bonding metal. For example, the second metal layer 122 may include, at least one of Ti, Au, Sn, Ni, Cr, Ga, In, Bi, Cu, Ag and Ta, but the present disclosure is not limited thereto.

The reflective layer 124 may be disposed between the second metal layer 122 and the ohmic layer 126. The reflective layer 124 may be made of a material exhibiting excellent reflection characteristics, for example, a material selected from Ag, Ni, Al, Rh, Pd, Ir, Ru, Mg, Zn, Pt, Au, Hf, and a selective combination thereof. Alternatively, the reflective layer 124 may be formed to have a single-layer or multilayer structure, using the above-described material and a transparent conductive material such as IZO, IZTO, IAZO, IGZO, IGTO, AZO, and ATO.

In addition, the reflective layer 124 may have a stackedstructure of IZO/Ni, AZO/Ag, TZO/Ag/Ni, or AZO/Ag/Ni. When the reflective layer 124 is made of a material capable of ohmic-contacting the light emitting structure 140, it may be unnecessary to separately form the ohmic layer 126, but the present disclosure is not limited thereto.

The ohmic layer 126 ohmic-contacts a lower surface of the light emitting structure 140. The ohmic layer 126 takes the form of a layer or a plurality of patterns. The ohmic layer 126 may be formed through selective use of a transparent electrode and a metal. For example, the ohmic layer 126 may have a single-layer or multilayer structure, using at least one of indium tin oxide (ITO), indium zinc oxide (IZO), indium zinc tin oxide (IZTO), indium aluminum zinc oxide (IAZO), indium gallium zinc oxide (IGZO), indium gallium tin oxide (IGTO), aluminum zinc oxide (AZO), antimony tin oxide (ATO), gallium zinc oxide (GZO), IrOₓ, RuOₓ, RuOₓ/ITO, Ni, Ag, Ni/IrOₓ/Au, and Ni/IrOₓ/Au/ITO. The ohmic layer 126 functions to smoothly achieve injection of carriers into the first semiconductor layer included in the light emitting structure 140. It may be unnecessary to form the ohmic layer 126.

A passivation layer 130 may be disposed on the first electrode 120, to cover side and upper surfaces of the light emitting structure 140.

In this case, the passivation layer 130 may be made of an insulating material. For example, the passivation layer 130 may be made of SiO₂, SiOₓ, SiOₓN_{y}, Si₃N₄, or Al₂O₃, but the present disclosure is not limited thereto.

In addition, the passivation layer 130 may be disposed to contact a side surface of the second electrode 150 disposed on the upper surface of the light emitting structure 140, but the present disclosure is not limited thereto.

The light emitting structure 140 may include a first semiconductor layer 142, an active layer 144, and a second semiconductor layer 146. The active layer 144 may be disposed between the first and second semiconductor layers 142 and 146.

The first semiconductor layer 142 may be implemented as a p-type semiconductor layer, to inject holes into the active layer 144. The first semiconductor layer 142 may be made of, for example, a semiconductor material having a formula of InₓAl_{y}Ga_{1-x-y}N (0≦x≦1, 0≦y≦1, and 0≦x+y≦1).

The material of the first semiconductor layer 142 may be selected from, for example, GaN, AlN, AlGaN, InGaN, InN, InAlGaN, AlInN, AlGaAs, GaP, GaAs, GaAsP, and AlGaInP. The first semiconductor layer 142 may be doped with a p-type dopant such as Mg, Zn, Ca, Sr or Ba.

The second semiconductor layer 146 is disposed on the active layer 144, to inject electrons into the active layer 144. The second semiconductor layer 146 may be made of, for example, a semiconductor material having a formula of InₓAl_{y}Ga_{1-x-y}N (0≦x≦1, 0≦y≦1, and 0≦x+y≦1).

The material of the second semiconductor layer 146 may be selected from, for example, GaN, AlN, AlGaN, InGaN, InN, InAlGaN, AlInN, AlGaAs, GaP, GaAs, GaAsP, and AlGaInP. The second semiconductor layer 146 may be doped with an n-type dopant such as Si, Ge, Sn, Se, or Te.

The active layer 144 disposed between the first and second semiconductor layer 142 may be formed to have a single quantum well structure, a multi-quantum well structure, a quantum wire structure or a quantum dot structure, using a material of Group II-VI or Group III-V compound semiconductors.

The active-layer 144 may have a single or multi-quantum well structure including a well layer having a formula of InₓAl_{y}Ga_{1-x-y}N (0≦x≦1, 0≦y≦1, and 0≦x+y≦1) and a barrier layer having a formula of InₐAl_{b}Ga_{1-a-b}N (0≦a≦1, 0≦b≦1, and 0≦a+b≦1). The well layer may be made of a material having a lower band gap than the barrier layer.

A conductive clad layer (not shown) may be disposed on and/or beneath the active layer 144. The conductive clad layer may be made of an AlGaN-based semiconductor. The conductive clad layer may have a higher band gap than the active layer 144.

Meanwhile, an insert layer (not shown) may be disposed between the active layer 144 and the first semiconductor layer 142. The insert layer may be an electron blocking layer functioning to avoid a phenomenon in which, during application of high current, electrons injected from the second semiconductor layer 146 into the active layer 144 flow into the first semiconductor layer 142 without recombination thereof in the active layer 144.

The insert layer may have a higher band gap than the barrier layer included in the active layer 144. The insert layer may be made of a semiconductor material including Al, for example, p-type AlGaN. Since the insert layer has a higher band gap than the active layer 144, it may be possible to avoid a phenomenon in which electrons injected into the second semiconductor layer 146 are injected into the first semiconductor layer 142 without recombination thereof in the active layer 144. Accordingly, recombination probability of electrons and holes may be increased and, as such, generation of current leakage may be prevented.

The first semiconductor layer 142, active layer 144, and second semiconductor layer 146 may be formed using a metal organic chemical vapor deposition (MOCVD) method, a chemical vapor deposition (CVD) method, a plasma-enhanced chemical vapor deposition (PECVD) method, a molecular beam epitaxy (MBE) method, a hydride vapor phase epitaxy (HVPE) method, or a sputtering method. The formation method is not limited to the above-described methods.

The concentrations of the dopants in the first and second semiconductor layers 142 and 146 may be uniform or non-uniform. That is, the plural semiconductor layers may have various dopant concentration distributions, but the present disclosure is not limited thereto.

Meanwhile, the first semiconductor layer 142 may be implemented by an n-type semiconductor layer, and the second semiconductor layer 146 may be implemented by a p-type semiconductor layer. In addition, a third semiconductor layer (not shown) including an n or p-type semiconductor layer may be disposed on the second semiconductor layer 146. Accordingly, the light emitting device 100 may have at least one of np, pn, npn, and pnp junction structures.

As illustrated in FIG. 2, the second electrode 150 is disposed on an upper surface of the second semiconductor layer 146 and, as such, supplies current through the upper surface of the second semiconductor layer 146.

The second electrode 150 may be formed to have a single layer or multilayer structure, using a conductive material, for example, a metal selected from In, Co, Si, Ge, Au, Pd, Pt, Ru, Re, Mg, Zn, Hf, Ta, Rh, Ir, W, Ti, Ag, Cr, Mo, Nb, Al, Ni, Cu, and WTi, or an alloy thereof.

The second electrode 150 may include a pad electrode 152 disposed at one side of the second semiconductor layer 146, and a branch electrode 154 extending from the pad electrode 152 while having hexagonal frames to expose the upper surface of the second semiconductor layer 146 through hexagonal openings defined by the hexagonal frames.

In the second electrode 150 of the illustrated embodiment, the pad electrode 152 is disposed at one corner of the upper surface of the second semiconductor layer 146, and the branch electrode 154 is disposed at a portion of the upper surface of the second semiconductor layer 146, except for the above-described corner, while having hexagonal frames, as described above. However, at least two pad electrodes 152 may be disposed at symmetrical corners of the upper surface of the second semiconductor layer 146. The pad electrode 152 may be disposed at a portion of the upper portion of the second semiconductor layer 146. The present disclosure is not limited to the above-described conditions.

Meanwhile, the branch electrode 154 may have circular, oval or polygonal frames in place of the hexagonal frames, but the present disclosure is not limited thereto.

When the pad electrode 152 is disposed at a lead frame (not shown) included in a light emitting device package (not shown), as shown in FIG. 3, the pad electrode 152 is electrically connected to the lead frame via a wire (not shown). In this regard, the pad electrode 152 may have a certain area.

In this case, the branch electrode 154 has hexagonal frames, and is disposed on the upper surface of the second semiconductor layer 146, to supply electric power applied thereto to the second semiconductor layer 146 in a diffused manner.

That is, since the branch electrode 154 has hexagonal frames, electric power supplied to the pad electrode 152 is diffused to 6 sides of each hexagonal frame and, as such, is uniformly supplied to the second semiconductor layer 146. Accordingly, current concentration may be prevented.

In this case, the width of each of the 6 sides in each frame of the branch electrode 154, namely, d1, may be 1 μm to 5 μm.

That is, when the branch electrode 154 has a width d1 of less than 1 μm, at least one of the 6 sides may be broken during formation of the 6 sides and, as such, process efficiency may be decreased. On the other hand, when the branch electrode 154 has a width d1 of more than 5 μm, the exposed area of the upper surface of the second semiconductor layer 154 may be reduced, even though the 6 sides may be easily formed. As a result, light emission efficiency may be decreased due to a reduction in light emission area.

The thickness of each of the 6 sides in each frame of the branch electrode 154, namely, d2, may be equal to or more than the width d1, but the present disclosure is not limited thereto.

That is, when the thickness d2 of each side in the branch electrode 154 is less than the width d1, at least one of the 6 sides may be broken during formation of the 6 sides. In addition, the cross-sectional area of each side is reduced and, as such, an increase in resistance may occur. As a result, diffusion of current supplied from the pad electrode 152 may be difficult. On the other hand, when the thickness d2 of each side is equal to or more than the width d1, the cross-sectional area of each side is increased and, as such, a decrease in resistance may occur. As a result, diffusion of current supplied from the pad electrode 152 may be easily carried out.

In addition, the lengths of the 6 sides in each frame of the branch electrode 154, namely, d3, may be equal. Alternatively, at least one of the 6 sides may have a length d3 different from those of the remaining sides. The present disclosure is not limited to the above-described conditions.

In the illustrated embodiment, the branch electrode 154 has hexagonal frames each having the same length d3 at the 6 sides thereof.

That is, the length d3 of each side in the branch electrode 154 may be 220 μm to 230 μm. The distance from a center of each hexagonal frame to each side of the hexagonal frame, namely, d4, may be 190 μm to 200 μm., the present disclosure is not limited to the above-described conditions.

When the length d3 of each side in the branch electrode 154 is less than 220 μm, and the distance d4 is less than 190 μm, the hexagonal upper surface area of the second semiconductor layer 146 exposed through the branch area 154 is reduced and, as such, light emission efficiency may be decreased. When the length d3 of each side is more than 230 μm, and the distance d4 is more than 200 μm, the hexagonal upper surface area of the second semiconductor layer 146 exposed through the branch area 154 is increased and, as such, light emission efficiency may be enhanced. In this case, however, diffusion of current supplied from the pad electrode 152 may be reduced and, as such, there may be a possibility that current is concentrated on the portion of the second semiconductor layer 146 disposed adjacent the pad electrode 152.

As described above, current concentration may be prevented by uniformly supplying current to the upper surface of the second semiconductor layer 146 in accordance with the branch electrode 154 formed to have hexagonal frames. Accordingly, the second semiconductor layer 146 may uniformly provide electric charges to a center of the active layer 144 and side surfaces of the active layer 144 disposed at opposite sides of the center of the active layer 144 and, as such, there may be an advantage in that the light emission efficiency of the light emitting device 100 is enhanced.

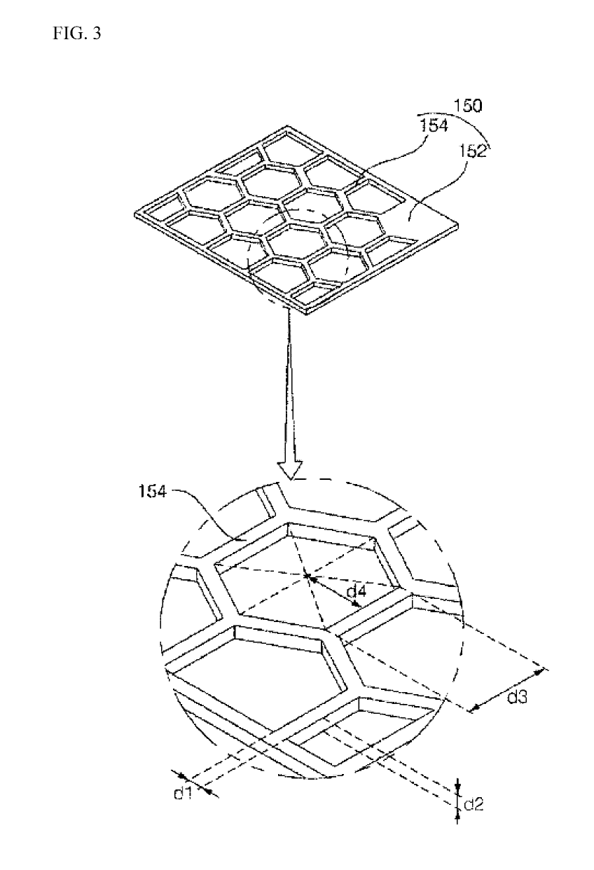

FIGS. 4 to 6 are sectional views illustrating various embodiments of the above-described light emitting device.

Referring to FIG. 4, the light emitting device, which is designated by reference numeral “200” includes a substrate 210, a first metal layer 212 disposed on the substrate 210, a first electrode 220 disposed on the first metal layer 212, and a passivation layer 230 disposed on the first electrode 220 while disposed on side surfaces of a light emitting structure 240. The light emitting device also includes the light emitting structure 240, which is disposed on the first electrode 220, and a second electrode 250 disposed on the light emitting structure 240.

Here, for a description of the substrate 210, first metal layer 212, first electrode 220 and passivation layer 230, reference may be made to FIGS. 1 and 2 and, as such, no description will be given.

The first electrode 220 may include a second metal layer 222, a reflective layer 224, and an ohmic layer 226, and for a description thereof, a reference may be made to description given in conjunction with FIGS. 1 to 3. Accordingly, no description thereof will be given.

The light emitting structure 240 may include a first semiconductor layer 242, an active layer 244, and a second semiconductor layer 246. The first semiconductor layer 242 is electrically connected to the first electrode 220, and may be a p-type semiconductor layer to supply holes to the active layer 244. The second semiconductor layer 246 is disposed on the active layer 244, and is electrically connected to the second electrode 250. The second semiconductor layer 246 may be an n-type semiconductor layer to supply electric charges to the active layer 244.

Here, for a description of the first semiconductor layer 242, active layer 244, and second semiconductor layer 246, reference may be made to description given in conjunction with FIGS. 1 and 2 and, as such, no detailed description thereof will be given, and only details different from those of FIGS. 1 and 2 will be described.

In addition, the first semiconductor layer 242, active layer 244, and second semiconductor layer 246 may have inclined side surfaces, but the present disclosure is not limited thereto.

As described in conjunction with FIGS. 1 to 3, the second electrode 250 may include an electrode pad (not shown) and a branch electrode 254. In the following description, the branch electrode 254 will be described as having hexagonal frames. Alternatively, the branch electrode 254 may have circular, oval or polygonal frames, but the present disclosure is not limited thereto.

The second semiconductor layer 246 may have a groove g in which the second electrode 250 having hexagonal frames is disposed. The groove g allows lower and side surfaces of the second electrode 250 to contact the second semiconductor layer 246 and, as such, increases the contact area between the second electrode 250 and the second semiconductor layer 246. Accordingly, diffusion of current supplied to the second electrode 250 may be increased, as compared to that of the light emitting device 100 illustrated in FIG. 1. The groove g has been illustrated as having a square cross-sectional shape, but the present disclosure is not limited thereto. The groove g may have a polygonal, circular or oval cross-sectional shape.

In this case, the groove g may have a depth b1 corresponding to 0.5 to 1 times the thickness d2 of the branch electrode 254 included in the second electrode 250.

That is, when the depth b1 of the groove g is less than 0.5 time the thickness d2 of the branch electrode 254, the contact area between the side surface of the branch electrode 254 and the portion of the second semiconductor layer 246 forming the side surface of the groove g is small and, as such, current diffusion effects are insufficient. When the depth b1 of the groove g is more than 1 times the thickness d2 of the branch electrode 254, there is no remarkable current diffusion effect, as compared to the case in which the depth b1 of the groove g is equal to 1 times the thickness d2 of the branch electrode 254. In this case, process efficiency may be decreased upon forming the branch electrode 254.

In addition, the groove g may have a width b2 equal to the width d1 of the branch electrode 254.

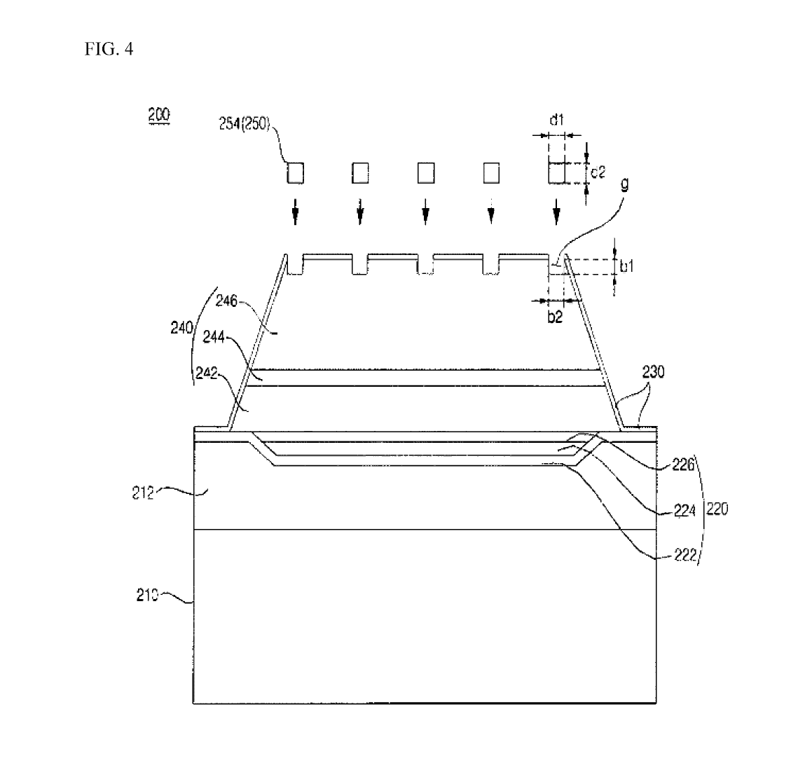

Referring to FIG. 5, the light emitting device, which is designated by reference numeral “300” includes a substrate 310, a first metal layer 312 disposed on the substrate 310, a first electrode 320 disposed on the first metal layer 312, a light emitting structure 340 disposed on the first electrode 320, a passivation layer 330 disposed on side surfaces of the light emitting structure 340, and a second electrode 350 disposed on the light emitting structure 340.

Here, for a description of the substrate 310, first metal layer 312, first electrode 320 and passivation layer 330, reference may be made to description given in conjunction with FIGS. 1 and 2 and, as such, no description thereof will be given.

The light emitting structure 340 may include a first semiconductor layer 342, an active layer 344, and a second semiconductor layer 346. The first semiconductor layer 342 is electrically connected to the first electrode 320, and may be a p-type semiconductor layer to supply holes to the active layer 344. The second semiconductor layer 346 is disposed on the active layer 344, and is electrically connected to the second electrode 350. The second semiconductor layer 346 may be an n-type semiconductor layer to supply electric charges to the active layer 344.

Here, for a description of the first semiconductor layer 342, active layer 344, and second semiconductor layer 346, reference may be made to description given in conjunction with FIGS. 1 and 2 and, as such, no detailed description thereof will be given, and only details different from those of FIGS. 1 and 2 will be described.

As described in conjunction with FIGS. 1 to 3, the second electrode 350 may include an electrode pad (not shown) and a branch electrode 354. In the following description, the branch electrode 354 will be described as having hexagonal frames. Alternatively, the branch electrode 354 may have circular, oval or polygonal frames, but the present disclosure is not limited thereto.

A light extraction structure p is disposed at the upper surface of the second semiconductor layer 346, to enhance light emission efficiency.

The light extraction structure p has been illustrated as being disposed on the upper surface of the second semiconductor layer 346. However, when a transparent electrode layer (not shown) is disposed on the second semiconductor layer 346, the light extraction structure p may be disposed on a portion of the upper surface of the transparent electrode layer or on the entirety of the upper surface of the transparent electrode layer.

The light extraction structure p may have a regular or irregular shape and arrangement. For example, the light extraction structure p may have protrusions each having a lateral section having a circular column, polygonal column, circular conical, polygonal conical, or truncated conical shape, but the present disclosure is not limited thereto.

In this case, the branch electrode 354 included in the second electrode 350 may be disposed on the light extraction structure p of the second semiconductor layer 346.

Although not shown in conjunction with the illustrated embodiment, a groove (not shown), in which the branch electrode 354 included in the second electrode 350 will be disposed, as illustrated in FIG. 4, may be disposed at a lower surface of the light extraction structure p disposed on the upper surface of the second semiconductor layer 346, but the present disclosure is not limited thereto.

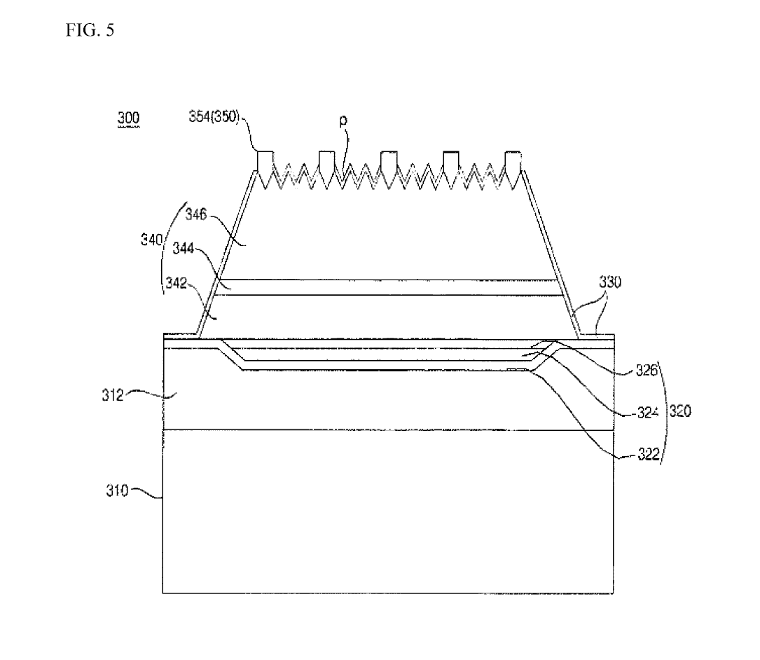

Referring to FIG. 6, the light emitting device, which is designated by reference numeral “400” includes a substrate 410, a first metal layer 412 disposed on the substrate 410, a first electrode 420 disposed on the first metal layer 412, a current blocking layer (CBL) 460 disposed on the first electrode 420, a light emitting structure 440 disposed on the first electrode 420 and the current blocking layer 460, a passivation layer 430 disposed on side surfaces of the light emitting structure 440, and a second electrode 450 disposed on the light emitting structure 440.

Here, for a description of the substrate 410, first metal layer 412, first electrode 420 and passivation layer 430, reference may be made to description given in conjunction with FIGS. 1 and 2 and, as such, no description thereof will be given.

The light emitting structure 440 may include a first semiconductor layer 442, an active layer 444, and a second semiconductor layer 446. The first semiconductor layer 442 is electrically connected to the first electrode 420, and may be a p-type semiconductor layer to supply holes to the active layer 444. The second semiconductor layer 446 is disposed on the active layer 444, and is electrically connected to the second electrode 450. The second semiconductor layer 446 may be an n-type semiconductor layer to supply electric charges to the active layer 444.

Here, for a description of the first semiconductor layer 442, active layer 444, and second semiconductor layer 446, reference may be made to description given in conjunction with FIGS. 1 and 2 and, as such, no detailed description thereof will be given, and only details different from those of FIGS. 1 and 2 will be described.

As described in conjunction with FIGS. 1 to 3, the second electrode 450 may include an electrode pad (not shown) and a branch electrode 454. In the following description, the branch electrode 454 will be described as having hexagonal frames. Alternatively, the branch electrode 454 may have circular, oval or polygonal frames, but the present disclosure is not limited thereto.

The current blocking layer 460 may be disposed on the first electrode 320, to partially vertically overlap the branch electrode 454 included in the second electrode 450.

The current blocking layer 460 may be made of at least one of a material having electrical insulation properties, a material having a lower electrical conductivity than the first electrode 420 or first metal layer 412, and a material capable of forming a Schottky contact with the first semiconductor layer 442. For example, the current blocking layer 460 may be made of at least one of SiO₂, SiOₓ, SiOₓN_{y}, Si₃N₄, Al₂O₃, TiOₓ, TiO₂, Ti, Al, Pt and Cr.

The current blocking layer 460 is disposed between the first electrode 420 and the light emitting structure 440 while vertically overlapping the branch electrode 454 and, as such, may prevent concentration of current supplied to the first semiconductor layer 442.

In this case, the current blocking layer 460 may be formed to have the same hexagonal frames as the branch electrode 454, but the present disclosure is not limited thereto.

As illustrated in FIG. 6, the current blocking layer 460 is not disposed at positions vertically overlapping portions of the branch electrode 454 disposed at edge portions of the second semiconductor layer 446, but may be disposed to vertically overlap portions of the branch electrode 454 disposed at a central portion of the second semiconductor layer 446, except for the edge portions of the second semiconductor layer 446. The present disclosure is not limited to the above-described condition.

In this case, the width of the current blocking layer 460, namely, b3, may be 1 to 2 times the width d1 of the branch electrode 454.

That is, when the width b3 of the current blocking layer 460 is less than 1 times the width d1 of the branch electrode 454, the possibility that concentration of current supplied to the first semiconductor layer 452 corresponding to the branch electrode 454 occurs is increased. When the width b3 of the current blocking layer 460 is more than 2 time the width d1 of the branch electrode 454, it may be possible to prevent concentration of current supplied to the first semiconductor layer 452. However, although the width b3 of the current blocking layer 460 increases over 2 time the width d1 of the branch electrode 454, the effect of preventing current concentration is no longer increased. Rather, an increase in manufacturing costs may occur.

Although the light emitting devices 200, 300, and 400 illustrated in FIGS. 4 to 6 have different structures, they may be combined. The present disclosure is not limited to the above-described condition.

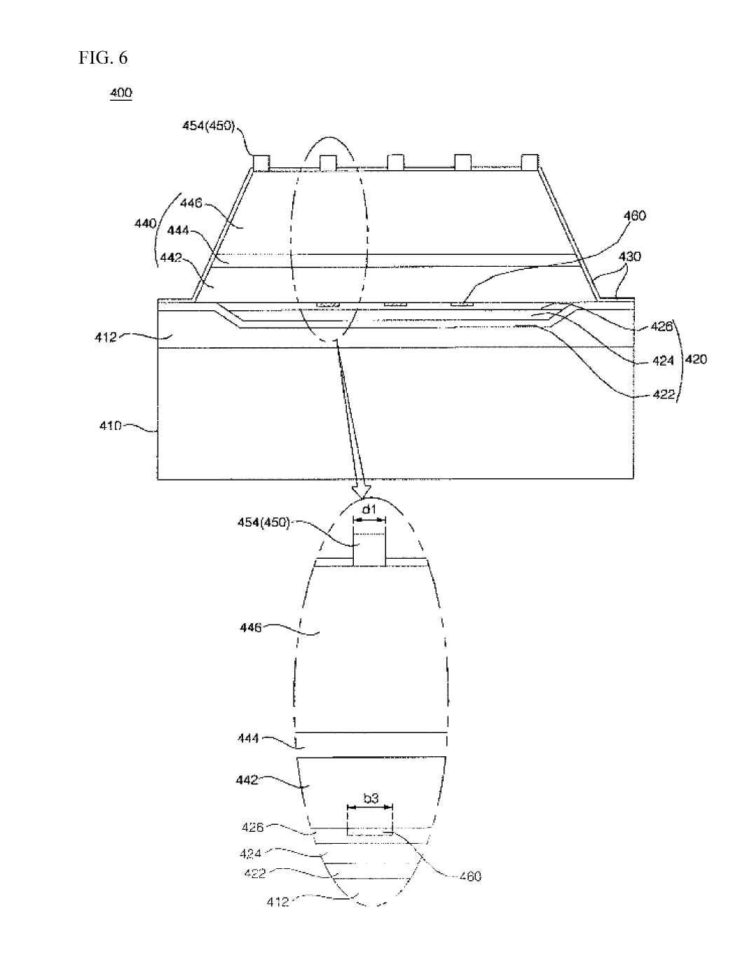

FIG. 7 is an exploded perspective view illustrating a display apparatus according to a first embodiment.

Referring to FIG. 7, the display apparatus according to the illustrated embodiment, which is designated by reference numeral 1000, may include a light guide plate 1041, a light source module 1031 for supplying light to the light guide plate 1041, a reflective member 1022 disposed beneath the light guide plate 1041, an optical sheet 1051 disposed on the light guide plate 1041, a display panel 1061 disposed on the optical sheet 1051, and a bottom cover 1011 for receiving the light guide plate 1041, light source module 1031 and reflective member 1022.

The bottom cover 1011, reflective member 1022, light guide plate 1041 and optical sheet 1051 may be defined as a light unit 1050.

The light guide plate 1041 functions to diffuse light, thereby emitting planar light. The light guide plate 1041 is made of a transparent material. For example, the material of the light guide plate 1041 may include one of acrylic resin such as polymethylmethacrylate (PMMA) and other resins such as polyethylene terephthalate (PET), polycarbonate (PC), cycloolefin copolymer (COC), and polyethylene naphthalate (PEN).

The light source module 1031 supplies light to at least one side surface of the light guide plate 1041. Consequently, the light source module 1031 functions as a light source of the display apparatus.

At least one light source module 1031 is provided. The light source module 1031 may directly or indirectly supply light at one side of the light guide plate 1041. The light source module 1031 may include a substrate 1033, and light emitting device packages 1035 according to the above-described embodiment. The light emitting device packages 1035 may be arrayed on the substrate 1033 while being uniformly spaced from one another.

The substrate 1033 may be a printed circuit board (PCB) including a circuit pattern (not shown). The substrate 1033 may include a general PCB, a metal core PCB (MCPCB), or a flexible PCB (FPCB), but the present disclosure is not limited thereto. When the light emitting device packages 1035 are mounted on a side surface of the bottom cover 1011 or on a heat dissipation plate, the substrate 1033 may be omitted. In this case, a portion of the heat dissipation plate may contact the upper surface of the bottom cover 1011.

The plurality of light emitting device packages 1035 may be mounted on the substrate 1033 such that light emission surfaces thereof are spaced from the light guide plate 1041 by a predetermined distance, but the present disclosure is not limited thereto. The light emitting device packages 1035 may directly or indirectly supply light to a light incidence portion of the light guide plate 1041, namely, one side surface of the light guide plate 1041, but the present disclosure is not limited thereto.

The reflective member 1022 may be disposed beneath the light guide plate 1041. The reflective member 1022 reflects light incident upon the lower surface of the light guide plate 1041 is directed upwards, thereby achieving an enhancement in brightness of the light unit 1050. The reflective member 1022 may be made of resin such as PET, PC or PVC, but the present disclosure is not limited thereto. The reflective member 1022 may be the upper surface of the bottom cover 1011, but the present disclosure is not limited thereto.

The bottom cover 1011 may receive the light guide plate 1041, light source module 1031, reflective member 1022, etc. To this end, the bottom cover 1011 may include a receiver 1012 having a box shape open at a top surface thereof, but the present disclosure is not limited thereto. The bottom cover 1011 may be coupled to a top cover, but the present disclosure is not limited thereto.

The bottom cover 1011 may be made of metal or resin. The bottom cover 1011 may be fabricated using a process such as pressing or extrusion. In addition, the bottom cover 1011 may include a metal material exhibiting excellent thermal conductivity or a non-metal material, but the present disclosure is not limited thereto.

The display panel 1061 is, for example, a liquid crystal display (LCD) panel. The display panel 1061 includes facing first and second substrates made of a transparent material, and a liquid crystal layer disposed between the first and second substrates. A polarization plate may be attached to at least one surface of the display panel 1061, but the present disclosure is not limited to the structure in which the polarization plate is attached. The display panel 1061 displays information using light passing through the optical sheet 1051. The display apparatus 1000 may be applied to various portable terminals, monitors of notebook computers, monitors of laptop computers, televisions, etc.

The optical sheet 1051 is disposed between the display panel 1061 and the light guide plate 1041. The optical sheet 1051 includes at least one transparent sheet. The optical sheet 1051 may include at least one sheet selected from, for example, a diffusion sheet, horizontal and vertical prism sheets and a brightness enhancing sheet. The diffusion sheet functions to diffuse incident light. The horizontal and/or vertical prism sheet focuses incident light on a display area. The brightness enhancing sheet enhances brightness through re-use of light that would otherwise be lost. In addition, a protective sheet may be disposed on the display panel 1061, but the present disclosure is not limited thereto.

The light guide plate 1041 and optical sheet 1051 may be disposed in an optical path of the light source module 1031, as optical members, but the present disclosure is not limited thereto.

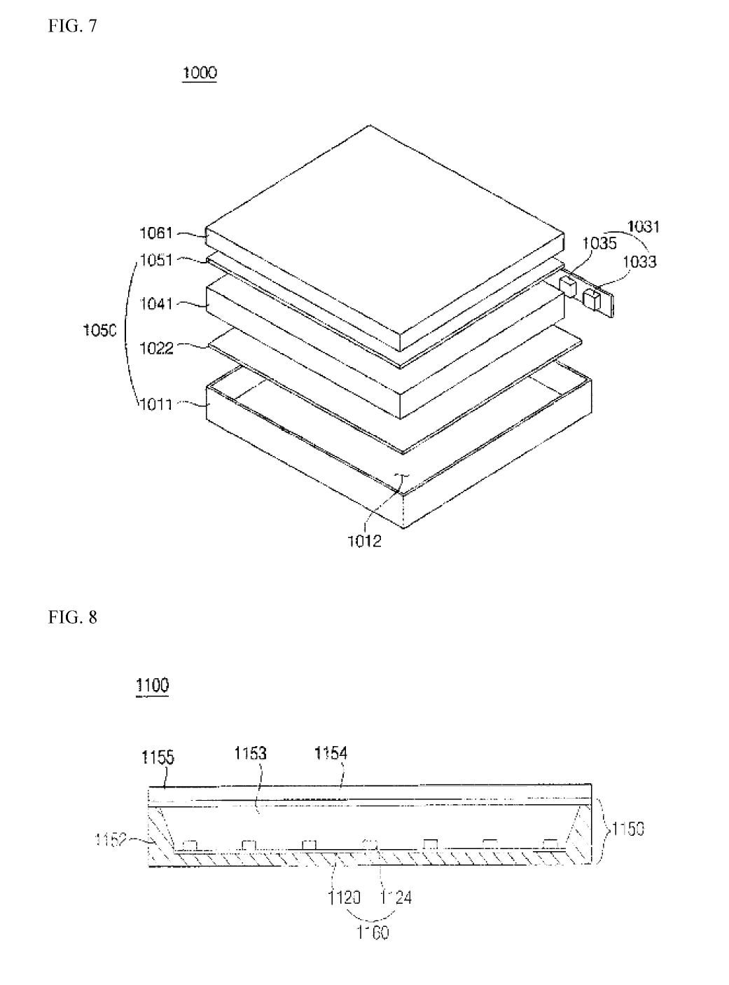

FIG. 8 is a sectional view illustrating a display apparatus according to a second embodiment.

Referring to FIG. 8, the display apparatus according to the illustrated embodiment, which is designated by reference numeral 1100, includes a bottom cover 1152, a substrate 1120, on which the above-described light emitting devices, namely, light emitting device packages 1124, are arrayed, an optical member 1154, and a display panel 1155.

The substrate 1120 and light emitting device packages 1124 may be defined as a light source module 1160. The bottom cover 1152, at least one light source module 1160 and the optical member 1154 may be defined as a light unit 1150. The bottom cover 1152 may include a receiver 1153, but the present disclosure is not limited thereto. The light source module 1160 includes the substrate 1120, and a plurality of light emitting device packages 1124 arrayed on the substrate 1120.

The optical sheet 1154 may include at least one of a lens, a light guide plate, a diffusion sheet, horizontal and vertical prism sheets and a brightness enhancing sheet. The light guide plate may be made of a material such as PC or PMMA. The light guide plate may be omitted. The diffusion sheet functions to diffuse incident light. The horizontal and/or vertical prism sheet focuses incident light on a display area. The brightness enhancing sheet enhances brightness through re-use of light that would be otherwise be lost.

The optical member 1154 is disposed on the light source module 1160. The optical member 1154 functions to change light emitted from the light source module 1160 into planar light, or performs diffusion or focusing of the light.

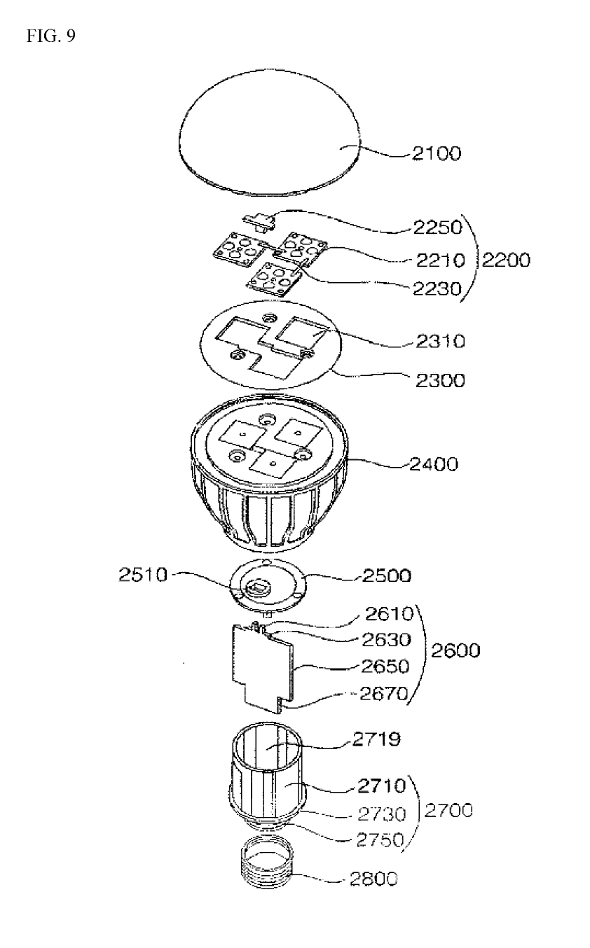

FIG. 9 is an exploded perspective view illustrating a lighting apparatus according to an embodiment.

Referring to FIG. 9, the lighting apparatus according to the illustrated embodiment may include a cover 2100, a light source module 2200, a radiator 2400, a power supply 2600, an inner case 2700, and a socket 2800. The lighting apparatus according to the illustrated embodiment may further include at least one of a support member 2300 and a holder 2500. The light source module 2200 may include a light emitting device package according to the above-described embodiment.

For example, the cover 2100 has a hollow bulb or hemispherical structure open at a portion thereof. The cover 2100 may be optically coupled to the light source module 2200. For example, the cover 2100 may diffuse, scatter or excite light supplied from the light source module 2200. The cover 2100 may be a kind of optical member. The cover 2100 may be coupled to the radiator 2400. The cover 2100 may have a coupling portion to be coupled to the radiator 2400.

A milk-white paint may be coated over an inner surface of the cover 2100. The milk-white paint may include a diffusion agent for diffusing light. The inner surface of the cover 2100 may have greater surface roughness than an outer surface of the cover 2100. In this case, accordingly, it may be possible to emit light from the light source module 2200 outwards after being sufficiently scattered and diffused.

The cover 2100 may be made of glass, plastic, polypropylene (PP), polyethylene (PE), polycarbonate (PC) or the like. Polycarbonate exhibits excellent light resistance, heat resistance and strength. The cover 2100 may be transparent to allow the light source module 2200 to be viewed from outside. Alternatively, the cover 2100 may be opaque. The cover 2100 may be foirlied through blow molding.

The light source module 2200 may be disposed on one surface of the radiator 2400. Accordingly, heat from the light source module 2200 is transferred to the radiator 2400. The light source module 2200 may include a light emitting device 2210, a connecting plate 2230, and a connector 2250.

The support member 2300 is disposed on the radiator 2400. The support member 2300 is provided with guide holes 2310 for receiving a plurality of light emitting device packages 2210 and the connector 2250. The guide holes 2310 correspond to the substrates of the light emitting device packages 2210 and the connector 2250, respectively.

Surfaces of the support member 2300 may be coated with a light reflective material. For example, the surfaces of the support member 2300 may be coated with a white paint. The support member 2300 receives light returning toward the light source module 2200 after being reflected from the inner surface of the cover 2100, and again reflects the received light toward the cover 2100. Accordingly, the support member 2300 enhances light efficiency of the lighting apparatus according to the illustrated embodiment.

The support member 2300 may be made of, for example, an insulating material. The connecting plate 2230 of the light source module 2200 may include a material having electrical conductivity. Accordingly, electrical contact may be provided between the radiator 2400 and the connecting plate 2230. When the support member 2300 is made of an insulating material, the support member 2300 may prevent electrical short circuit between the connecting plate 2230 and the radiator 2400. The radiator 2400 receives heat from the light source module 2200 and heat from the power supply 2600, and dissipates the received heat.

The holder 2500 closes a receiving hole 2719 provided at an insulating portion 2710 of the inner case 2700. Accordingly, the power supply 2600, which is received in the insulating portion 2710 of the inner case 2700, is sealed. The holder 2500 has a guide protrusion 2510. The guide protrusion 2510 may be provided with a hole, through which a protrusion 2610 of the power supply 2600 extends.

The power supply 2600 supplies an electrical signal received from outside to the light source module 2200 after processing or converting the received electrical signal. The power supply 2600 is received in the receiving hole 2719 of the inner case 2700, and is sealed in the inner case 2700 by the holder 2500.

The power supply 2600 may include a protrusion 2610, a guide 2630, a base 2650, and a protrusion 2670.

The guide 2630 has a shape protruding outwards from one side of the base 2650. The guide 2630 may be inserted into the holder 2500. A plurality of elements may be disposed on one surface of the base 2650. The elements may include an AC-DC converter for converting AC power supplied from an external power source into DC power, a drive chip for controlling driving of the light source module 2200, an electrostatic discharge (ESD) protecting device for protecting the light source module 2200, etc., but the present disclosure is not limited thereto.

The protrusion 2670 has a shape protruding outwards from the other side of the base 2650. The protrusion 2670 is inserted into a connecting portion 2750 of the inner case 2700, to receive an electrical signal from outside. For example, the protrusion 2670 may have a width equal to or less than the connecting portion 2750 of the inner case 2700. One end of a positive electrical wire and one end of a negative electrical wire may be electrically connected to the protrusion 2670. The other end of the positive electrical wire and the other end of the negative electrical wire may be electrically connected to the socket 2800.

The inner case 2700 may include a mold received therein together with the power supply 2600. The mold is formed as a molding solution is solidified. The mold functions to maintain the power supply 2600 within the inner case 2700 in a fixed state.

It is noted that the configuration of the above-described light emitting device package is not limited to the above described embodiments and all or a part of the embodiments may be selectively combined with one another to realize various modifications.

In addition, general terms used in this invention should be construed based on dictionary definition, or context, and should not be construed too broadly or too narrowly.

Also, unless particularly defined otherwise, technological terms used herein should be construed as having a meaning that is generally understood by those having ordinary skill in the art to which the invention pertains

Incidentally, unless clearly used otherwise, expressions in the singular number include a plural meaning. In this application, the terms “comprising” and “including” should not be construed to necessarily include all of the elements disclosed herein, and should be construed not to include some of the elements, or should be construed to further include additional elements.

Although exemplary embodiments have been disclosed for illustrative purposes, those skilled in the art will appreciate that various modifications, additions and substitutions are possible, without departing from the scope and spirit of the invention as disclosed in the accompanying claims.

1-20. (canceled)

21. A light emitting device comprising:
a substrate;
a first electrode disposed on the substrate;
a light emitting structure disposed on the first electrode, the light emitting structure comprising a first semiconductor layer, a second semiconductor layer and an active layer disposed between the first and second semiconductor layers; and
a second electrode disposed on the second semiconductor layer,
wherein the second electrode comprises
a pad electrode, and
a branch electrode extending from the pad electrode while having hexagonal frames, and
wherein an upper surface of the second semiconductor layer is exposed to have exposed portions having a hexagonal shape by the branch electrode.

22. The light emitting device active according to claim 21, wherein the pad electrode is disposed at one corner of the second semiconductor layer.

23. The light emitting device according to claim 21, wherein the branch electrode has a width of 1 to 5 μm.

24. The light emitting device according to claim 21, wherein the branch electrode has a thickness of 1 to 10 μm.

25. The light emitting device according to claim 21, wherein the branch electrode has a length of 220 to 230 μm.

26. The light emitting device according to claim 21, wherein the second semiconductor layer is formed with a groove in which the branch electrode is disposed.

27. The light emitting device according to claim 26, wherein the branch electrode has a thickness corresponding to 1 to 2 times a depth of the groove.

28. The light emitting device according to claim 26, wherein the groove has a polygonal or oval cross-sectional shape.

29. The light emitting device according to claim 21, further comprising:
a current blocking layer interposed between the first electrode and the first semiconductor layer,
wherein at least a portion of the current blocking layer vertically overlaps the branch electrode.

30. The light emitting device according to claim 29, wherein the current blocking layer has the same hexagonal frames as the branch electrode.

31. The light emitting device according to claim 29, wherein the current blocking layer has a width corresponding to 1 to 2 times a width of the branch electrode.

32. The light emitting device according to claim 21, further comprising:
a passivation layer disposed on side and upper surfaces of the light emitting structure,
wherein the passivation layer comprises at least one of SiO₂, SiOₓ, SiOₓN_{y}, Si₃N₄ and Al₂O₃.

33. The light emitting device according to claim 32, wherein the branch electrode contacts at least one of upper and side surfaces of the passivation layer.

34. The light emitting device according to claim 21, wherein:
the branch electrode has six sides defining each of the hexagonal frames; and
one of the six sides is spaced from a center of the hexagonal frame by a distance of 190 to 200 μm.

35. A light emitting device comprising:
a substrate;
a first electrode disposed on the substrate;
a light emitting structure disposed on the first electrode, the light emitting structure comprising a first semiconductor layer, a second semiconductor layer and an active layer disposed between the first and second semiconductor layers;
a second electrode disposed on the second semiconductor layer; and
a current blocking layer disposed between the first electrode and the first semiconductor layer,
wherein the first electrode comprises
a metal layer,
a reflective layer, and
a ohmic layer,
wherein the second electrode comprises
a pad electrode, and
a branch electrode extending from the pad electrode while having hexagonal frames,
wherein at least a portion of the current blocking layer vertically overlaps the branch electrode
wherein the current blocking layer has the same hexagonal frames as the branch electrode.

36. The light emitting device according to claim 35, wherein the current blocking layer has a width corresponding to 1 to 2 times a width of the branch electrode.

37. The light emitting device according to claim 35, wherein an upper surface of the second semiconductor layer is exposed to have exposed portions having a hexagonal shape by the branch electrode.

38. A light emitting device comprising:
a substrate;
a first metal layer disposed on the substrate;
a first electrode disposed on the first metal layer;
a light emitting structure disposed on the first electrode, the light emitting structure comprising a first semiconductor layer, a second semiconductor layer and an active layer disposed between the first and second semiconductor layers;
a second electrode disposed on the second semiconductor layer; and
a current blocking layer disposed between the first electrode and the first semiconductor layer,
wherein the first electrode comprises
a second metal layer,
a reflective layer disposed on the second metal layer, and
a ohmic layer disposed on the reflective layer,
wherein the second electrode comprises
a pad electrode, and
a branch electrode extending from the pad electrode while having hexagonal frames,
wherein at least a portion of the current blocking layer vertically overlaps the branch electrode,
wherein the current blocking layer has the same hexagonal frames as the branch electrode,
wherein the second metal layer has a recess portion, and
wherein the reflective layer and the ohmic layer are disposed in the recess portion of the second metal layer.

39. The light emitting device according to claim 38, wherein the second metal layer directly contacts with the light emitting structure.

40. The light emitting device according to claim 38, wherein a light extraction structure is disposed on an upper surface of the second semiconductor layer.
